(19) United States
(12) Patent Application Publication
(10) Pub. No.: US 2024/0369498 A1
(43) Pub. Date: Nov. 7, 2024

(54) WIRE MELTING TRACE PHOTOGRAPHING APPARATUS, APPARATUS AND METHOD OF DETERMINING ELECTRIC WIRE-MELTING TRACE BASED ON DEEP LEARNING

(71) Applicant: REPUBLIC OF KOREA (NATIONAL FORENSIC SERVICE DIRECTOR MINISTRY OF THE INTERIOR AND SAFETY), Wonju-si (KR)

(72) Inventors: Kyu Young LIM, Wonju-si (KR); Young Il SEO, Wonju-si (KR); Byung Seon MOON, Busan (KR); Jin Pyo KIM, Daejeon (KR)

(21) Appl. No.: 18/228,256

(22) Filed: Jul. 31, 2023

(30) Foreign Application Priority Data
May 3, 2023 (KR) 10-2023-0057809

(51) Int. Cl. G01N 21/952; G01N 21/88; G06T 7/00; H04N 23/54

(52) U.S. Cl. CPC G01N 21/952; G01N 21/8851; G06T 7/0002; H04N 23/54; G01N 2021/8887; G01N 2201/101; G01N 2201/103; G01N 2201/126; G06T 2207/20081; G06T 2207/20084; G06T 2207/30136; G06T 2207/30204

(57) ABSTRACT

A wire melting trace photographing apparatus according to an embodiment includes a wire fixing member connected to one side of a wire including a melting trace and fixing the wire, and a photographing member capable of photographing the melting trace in a circumferential direction of the wire. A deep learning-based electric wire-melting trace determination apparatus according to an embodiment includes an image obtaining unit configured to obtain a wire image for each rotation angle, a trained model application unit configured to calculate a determination probability of the wire image for each rotation angle, a melting trace analysis unit configured to analyze information related to a determination probability of a melting trace included in the wire, and a melting trace determination unit configured to determine the melting trace included in the wire according to a set determination condition.

### CROSS-REFERENCE TO RELATED APPLICATIONS

The present application is based on and claims priority to Korean Patent Application No. 10-2023-0057809 filed on May 3, 2023, in the Korean Intellectual Property Office, which is incorporated herein by reference in its entirety.

### BACKGROUND

### 1. Field

One or more embodiments relate to a wire melting trace photographing apparatus, and an apparatus and a method of determining an electric wire-melting trace based on deep learning.

### 2. Description of the Related Art

In investigating the causes of fire, explosion, arson, and crime, whether or not an electrical melting trace is found is a very important clue in determining the possibility of ignition by electrical causes. This is because an electrical melting trace may be formed by igniting adjacent combustibles using electrical heat or sparks generated at the site as an ignition source.

However, when a fire occurs in the vicinity after an electrical melting trace is formed, the electrical melting trace may be melted by a flame of the fire. As the degree of melting by the flame increases, the electrical melting trace becomes similar to a shape in which a metal (copper, aluminum, etc.) is melted by the flame. Therefore, electrical melting traces found at actual fire sites may be ambiguous because their shapes are not clear.

In the meantime, in order to distinguish an electrical melting trace (an electrical melting mark) from a flame melting trace (a flame melting mark), a method of determining by examining fine melting traces using a microscope or the like has been mainly used.

### SUMMARY

One or more embodiments include an apparatus that photographs a 360° image of a melting trace of a wire in a circumferential direction of the wire.

One or more embodiments include an apparatus and a method capable of determining whether a melting trace left on a wire is formed by an electrical cause (an electrical melting mark) or a flame (a flame melting mark) by utilizing convolutional neural networks (CNN) from among deep learning techniques.

According to one or more embodiments, a wire melting trace photographing apparatus includes a wire fixing member connected to one side of a wire including a melting trace, positioning the wire away from a plane, and positioning a rotation axis of the wire parallel to the plane, and a photographing member capable of photographing the melting trace in a circumferential direction of the wire. The wire melting trace photographing apparatus may photograph the melting trace by directly rotating the wire about the rotation axis of the wire, or may photograph the melting trace in the circumferential direction of the wire by operating the photographing member in a state in which the wire is fixed.

In an embodiment, the wire fixing member may include a fixing jig for fixing one side of the wire to the side of the fixing jig, a wire fixing portion connected to one side of the fixing jig and located to fix the wire, a wire connection portion for connecting the fixing jig to the wire fixing portion so as to be rotatable about the rotation axis of the wire.

In an embodiment, the photographing member may include a photographing body for photographing the melting trace at a close distance, a photographing body fixing portion connected to one side of the photographing body and located so that the photographing body is fixed, and a photographing body connection portion rotatably connecting the photographing body to the photographing body fixing portion about the rotation axis of the wire.

The wire melting trace photographing apparatus may further include a support jig located to support a lower portion of the wire connected to the wire fixing member.

According to one or more embodiments, a deep learning-based electric wire-melting trace determination apparatus includes an image obtaining unit configured to obtain a wire image for each rotation angle captured using a wire melting trace photographing apparatus with respect to a wire including a melting trace, a trained model application unit configured to calculate a probability (determination probability) of determining a melting trace included in the wire image for each rotation angle as an electrical melting mark or a flame melting mark by applying a pre-trained model, a melting trace analysis unit configured to analyze information related to a determination probability of a melting trace included in the wire based on the determination probability of the melting trace included in the wire image for each rotation angle, and a melting trace determination unit configured to determine the melting trace included in the wire according to a set determination condition by analyzing the information.

In an embodiment, the information related to a determination probability of a melting trace included in the wire may include positive frequency of an electrical melting mark and a flame melting mark, an average determination probability of an electrical melting mark and a flame melting mark, a maximum determination probability of an electrical melting mark and a flame melting mark, a minimum determination probability of an electrical melting mark and a flame melting mark, or a standard deviation of a determination probability of an electrical melting mark and a flame melting mark.

In an embodiment, the deep learning-based electric wire-melting trace determination apparatus may further include a trained model generation unit configured to generate the pre-trained model using wire images found at a fire, explosion, or arson site as training data.

In an embodiment, the pre-trained model may be a convolutional neural network (CNN)-based deep learning model.

According to one or more embodiments, a deep learning-based electric wire-melting trace determination method includes omebtaining a wire image for each rotation angle captured using a wire melting trace photographing apparatus for a wire including a melting trace, calculating a probability (determination probability) of determining a melting trace included in the wire image for each rotation angle as an electrical melting mark or a flame melting mark by applying a pre-trained model, analyzing information related to a determination probability of a melting trace included in the wire based on the determination probability of the melting trace included in the wire image for each rotation angle, and determining the melting trace included in the wire according to a set determination condition by analyzing the information.

In an embodiment, the deep learning-based electric wire-melting trace determination method may further include generating the pre-trained model using wire images found at a fire, explosion, or arson site as training data.

In an embodiment, the wire image for each rotation angle may be an image captured at the same magnification.

Additional aspects will be set forth in part in the description which follows and, in part, will be apparent from the description, or may be learned by practice of the embodiments.

### BRIEF DESCRIPTION OF THE DRAWINGS

These and/or other aspects will become apparent and more readily appreciated from the following description of the embodiments, taken in conjunction with the accompanying drawings in which:

FIGS. 1A to 1C are schematic views of a wire melting trace photographing apparatus according to an embodiment;

FIG. 2 is a schematic block diagram of a deep learning-based electric wire-melting trace determination apparatus, according to an embodiment;

FIG. 3 is a view comparing determination probabilities according to rotation angles of wires;

FIG. 4 is a view comparing determination probabilities according to differences in magnification of wire images;

FIG. 5 is a view showing melting traces by a low melting point metal by way of example;

FIG. 6 is a view comparing an image of a single conductor of a cord with an image of a single wire;

FIG. 7 is a flowchart illustrating a deep learning-based electric wire-melting trace determination method according to an embodiment; and

FIG. 8 is a flowchart illustrating generating a pre-trained model according to an embodiment.

### DETAILED DESCRIPTION

Hereinafter, embodiments will be described in detail with reference to the accompanying drawings. The same reference numerals are used to denote the same elements, and repeated descriptions thereof will be omitted. It will be understood that although the terms “first,” “second,” etc. may be used herein to describe various elements, these elements should not be limited by these terms.

An expression used in the singular encompasses the expression of the plural, unless it has a clearly different meaning in the context. It will be further understood that the terms “comprises” and/or “comprising” used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

Sizes of elements in the drawings may be exaggerated for convenience of explanation. In other words, since sizes and thicknesses of components in the drawings are arbitrarily illustrated for convenience of description, the following embodiments are not limited thereto. When a certain embodiment may be implemented differently, a specific process order may be performed differently from the described order. For example, two consecutively described processes may be performed substantially at the same time or performed in an order opposite to the described order.

It will be understood that when a layer, region, or component is connected to another portion, the layer, region, or component may be directly connected to the portion or an intervening layer, region, or component may exist, such that the layer, region, or component may be indirectly connected to the portion.

In this specification, a ‘wire’ is an electrical conductor used to carry current from one point to another. The ‘wire’ is usually made of a metal or alloy with low electrical resistance, such as copper. The ‘wire’ is insulated with a non-conductive material, such as plastic or rubber, to prevent electric shock and prevent damage. The ‘wire’ is used for various purposes such as power transmission and distribution, communication, and electronic devices.

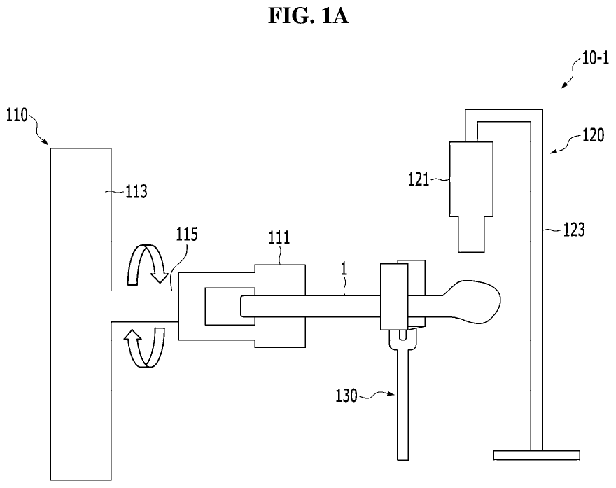

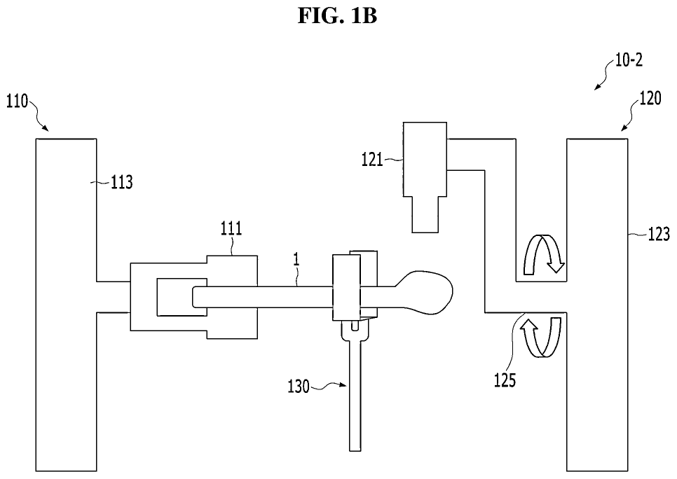

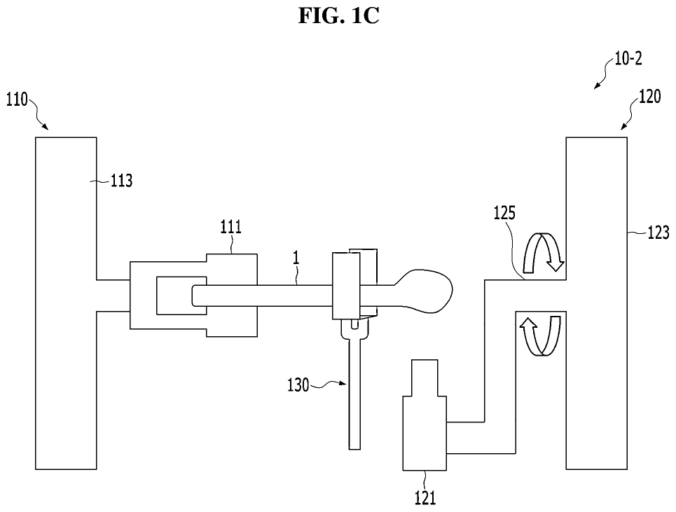

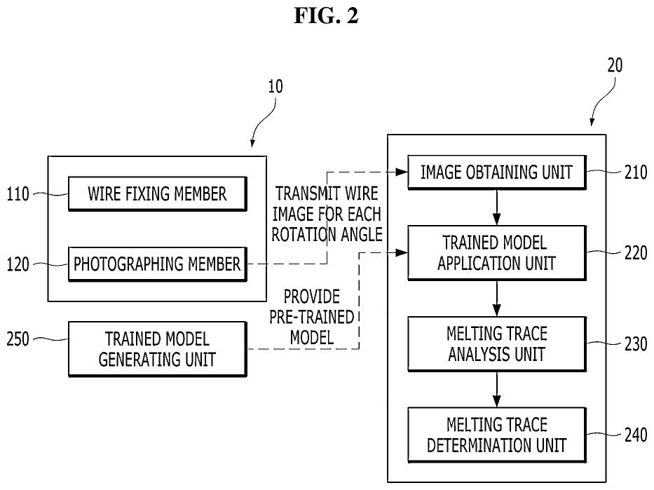

Hereinafter, referring to FIGS. 1A to 1C and FIG. 2, wire melting trace photographing apparatuses 10, 10-1 and 10-2 according to an embodiment will be described.

FIG. 1A is a schematic view of the wire melting trace photographing apparatus 10-1 according to an embodiment, and FIGS. 1B and 1C are schematic views of the wire melting trace photographing apparatus 10-2 according to an embodiment.

Referring to FIGS. 1A to 1C, the wire melting trace photographing apparatuses 10-1 and 10-2 may include a wire fixing member 110 and a photographing member 120.

A wire 1 is an electrical conductor and may be found at fire, explosion, arson, and crime scenes. A wire 1 found at an actual fire site may include a melting trace. The melting trace of the wire 1 found at the fire site is a very important clue in determining the possibility of ignition due to electrical causes.

The wire fixing member 110 is connected to one side of the wire 1 including the melting trace and positions the wire 1 away from a plane. In addition, the wire fixing member 110 may position a rotation axis of the wire 1 parallel to the plane.

The wire fixing member 110 may include a fixing jig 111, a wire fixing portion 113, and a wire connection portion 115.

The fixing jig 111 may fix one side of the wire 1 to the side of the fixing jig 111. The fixing jig 111 may position the rotation axis of the wire 1 parallel to the plane.

For example, as shown in the drawing, one end of the fixing jig 111 may be coupled and connected to the wire fixing portion 113, and the other end of the fixing jig 111 is separated into two parts and comes into contact with the wire 1 at two points, thereby fixing the wire 1 in the form of tongs.

The wire fixing portion 113 may be connected to one side of the fixing jig 111 and located such that the wire 1 is fixed.

In an embodiment, the wire fixing portion 113 may be formed in a vertical bar shape, and a lower portion thereof may be located on a plane. In another embodiment, the wire fixing portion 113 may have a plate shape or a polyhedral shape. As long as the fixing jig 111 can be fixed by connecting the wire fixing portion 113 to the fixing jig 111, the wire fixing portion 113 is not limited to a specific shape.

The wire connection portion 115 may connect the fixing jig 111 to the wire fixing unit 113 so as to be rotatable about the rotation axis of the wire 1.

For example, the wire connection portion 115 may be formed in a rotatable shaft shape. One end of the wire connection portion 115 may be coupled to the wire fixing portion 113, and the other end may be coupled to the fixing jig 111.

As an embodiment, an insertion groove is formed on one side of the wire fixing portion 113, and one end of the wire connection portion 115 may be rotated and inserted into an insertion groove to be coupled.

For example, a longitudinal direction of the wire 1 may be located horizontally, and the wire 1 may be rotated 360° about the rotation axis of the wire 1 through the rotation of the wire connection portion 115.

The wire fixing member 110 may further include a rotation angle display unit (not shown).

The rotation angle display unit allows an experimenter to check a rotation angle of the wire 1 with the naked eye. For example, the rotation angle display unit may be located on one side of the wire fixing unit 113, and an experimenter may check the rotation angle of the wire 1 according to the rotation of the wire connection portion 115.

The photographing member 120 may photograph a melting trace of the wire 1 in a circumferential direction of the wire 1. In addition, the photographing member 120 may include a photographing body 121, a photographing body fixing portion 123, and a photographing body connection portion 125.

The photographing body 121 is located at a close distance to the melting trace of the wire 1, and may photograph the melting trace. For example, the photographing body 121 may be a microscope or a camera capable of photographing the melting trace of the wire 1 at a close distance.

The photographing body fixing portion 123 may be connected to one side of the photographing body 121 and located such that the photographing body 121 is fixed.

For example, the photographing body fixing portion 123 may be formed in a vertical bar shape, and a lower portion thereof may be located on a plane. In another embodiment, the photographing body fixing portion 123 may have a plate shape or a polyhedral shape. As long as the photographing body 121 can be fixed by connecting the photographing body fixing portion 123 to the photographing body 121, the photographing body fixing portion 123 is not limited to a specific shape.

The photographing body connection portion 125 connects the photographing body 121 to the photographing body fixing portion 123, and enables the photographing body 121 to rotate around the rotation axis of the wire 1.

The photographing body connection portion 125 may connect the photographing body 121 to the photographing body fixing portion 123 so as to be rotatable about the rotation axis of the wire 1. For example, an insertion groove is formed on one side of the photographing body fixing portion 123, and one end of the photographing body connection portion 125 may be rotated and inserted into an insertion groove to be coupled.

As shown in the drawing, the wire melting trace photographing apparatus 10 according to an embodiment may further include a support jig 130.

The support jig 130 may be located to support a lower portion of the wire 1 connected to the wire fixing member 110.

The wire 1 may be located parallel to a plane with a rotation axis for 360° rotation photographing. Because the longitudinal direction of the wire 1 is located parallel to the plane, it is difficult to maintain the parallelism of the wire 1. At this time, the support jig 130 is located close to the melting trace of the wire 1 to support the lower portion of the wire 1, thereby stably maintaining and fixing the location of the wire 1.

For example, the support jig 130 may include a support portion for directly supporting the lower portion of the wire 1 and a height adjustment portion for adjusting the height of the support portion. The wire 1 is located away from the plane, and the height adjustment portion may be adjusted according to the height of the wire 1.

An operation method of the wire melting trace photographing apparatuses 10, 10-1 and 10-2 according to an embodiment will be separately described.

The wire 1 includes melting traces obtained from a fire site, and the melting traces are not uniformly formed on the wire 1. Accordingly, it is difficult to accurately determine whether a melting trace left on the wire 1 is an electrical melting trace (electrical melting mark) or a melting trace caused by a flame (flame melting mark).

For example, when the wire 1 is observed from an upper side, it can be determined as an electrical melting mark, and when observed from a lower side, it can be determined as a flame melting mark. Accordingly, it is necessary to photograph and observe the wire 1 from various directions.

360° photographing of a melting trace in a circumferential direction about the rotation axis of the wire 1 may be performed. A melting trace may be captured in a state in which the wire 1 is directly rotated about the rotation axis of the wire 1, or may be captured in the circumferential direction of the wire 1 by the operation of the photographing member 120 while the wire 1 is fixed.

Therefore, the wire melting trace photographing apparatuses 10, 10-1 and 10-2 may include the following embodiments.

### Wire Rotation Method

As an embodiment, as shown in FIG. 1A, the wire melting trace photographing apparatus 10-1 may directly rotate the wire 1 to capture a melting trace. In more detail, a melting trace may be captured by the photographing body 121 fixed in a state in which the wire 1 is directly rotated about the rotation axis of the wire 1. Accordingly, after setting intervals of constant rotation angles in the circumferential direction of the wire 1, wire images for each rotation angle may be obtained.

The wire connection portion 115 is connected to the fixing jig 111, and the wire 1 fixed to the fixing jig 111 may be rotated through rotation of the wire connection portion 115. In addition, the photographing body 121 may be located at a close distance to the melting trace of the wire 1, and may be fixed to the photographing body fixing portion 123.

### Wire Fixing Method

As another example, as shown in FIGS. 1B and 1C, the wire melting trace photographing apparatus 10-2 may photograph a melting trace by the operation of the photographing member 120 while the wire 1 is fixed. In more detail, a melting trace may be captured while the photographing body 121 for photographing the wire 1 rotates 360° in the circumferential direction of the wire 1.

After setting the interval of a certain rotation angle of the photographing body 121 in the circumferential direction of the wire 1 about the rotation axis of the wire 1, through the rotation of the photographing body connecting portion 125, a wire image for each rotation angle may be obtained.

At this time, the fixing jig 111 may be fixed to the wire fixing portion 113, and may fix the wire 1 parallel to a plane.

For example, an experimenter may set the interval of a rotation angle in the circumferential direction of the wire 1 to 1°, and may directly rotate the wire 1 or rotate the photographing body 121 to photograph one wire 1 360 times. Through this, multiple wire images for each rotation angle may be obtained. In this way, by photographing one wire 1 at various rotation angles, a melting trace may be more accurately determined.

Referring to FIG. 2, a deep learning-based electric wire-melting trace determination apparatus 20 according to an embodiment will be described.

FIG. 2 is a schematic block diagram of the deep learning-based electric wire-melting trace determination apparatus 20 according to an embodiment.

The deep learning-based electric wire-melting trace determination apparatus 20 in FIG. 2 shows only components related to the present embodiment in order to avoid obscuring features of the present embodiment. Accordingly, it is to be understood by one of ordinary skill in the art that other general-purpose components may be further included in addition to the components shown in FIG. 2.

The deep learning-based electric wire-melting trace determination apparatus 20 to which the present disclosure is applied may be various types of information processing devices used by users. For example, the deep learning-based electric wire-melting trace determination apparatus 20 may be a personal computer (PC), a laptop computer, a mobile phone, a tablet PC, a smart phone, or a personal digital assistant (PDA).

The deep learning-based electric wire-melting trace determination apparatus 20 according to an embodiment may include an image obtaining unit 210, a trained model application unit 220, a melting trace analysis unit 230, and a melting trace determination unit 240.

The image obtaining unit 210 may obtain an image of the wire 1 captured using the wire melting trace photographing apparatus 10 according to an embodiment.

In more detail, the image obtaining unit 210 may obtain a wire image for each rotation angle captured using the wire melting trace photographing apparatus 10 with respect to the wire 1 including a melting trace.

The image obtaining unit 210 may directly receive an image from the photographing body 121. In addition, the image obtaining unit 210 may receive images collected in a separate storage device from the photographing body 121.

The trained model application unit 220 may apply a pre-trained model to calculate a probability (determination probability) of determining a melting trace included in the wire image for each rotation angle as an electrical melting mark or a flame melting mark.

For example, when an experimenter sets a rotation angle of the wire 1 to 1°, a probability (determination probability) of being determined as an electrical melting mark or a flame melting mark may be calculated by applying a pre-trained model to 360 wire images for each rotation angle.

The pre-trained model applied here may be a convolutional neural network (CNN)-based deep learning model (CNN model). The CNN model recognizes unique patterns of images and classify the images based on the unique patterns. For example, in more detail, the CNN model may be any one of ALEXNET, ZFNET, VGGNET, GOOGLENET, RESNET, WIDE RESNET, VGG19, INCEPTION V3, INCEPTION V4, XCEPTION, SQUEEZENET, DENSENET, and MOBILENETS.

For example, in an image captured at a rotation angle of 90° in a circumferential direction of a copper wire 1 including a melting trace, the determination probability of the melting trace may be calculated as 66.10% of an electrical melting mark and 33.90% of a flame melting mark.

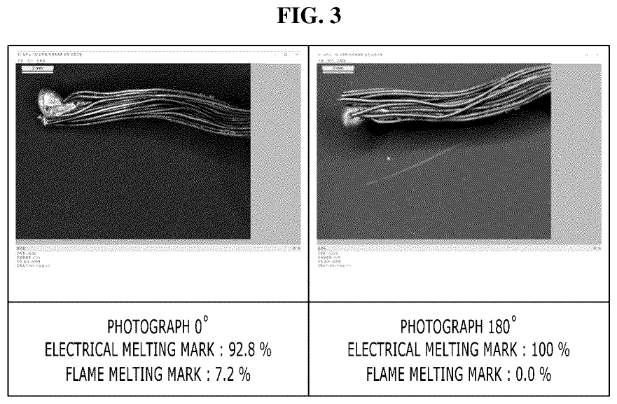

FIG. 3 is a view comparing determination probabilities according to rotation angles of wires.

Referring to FIG. 3, it can be seen that there is a difference in a determination probability between electrical melting marks and flame melting marks with different rotation angles (0° and 180°) in the same wire.

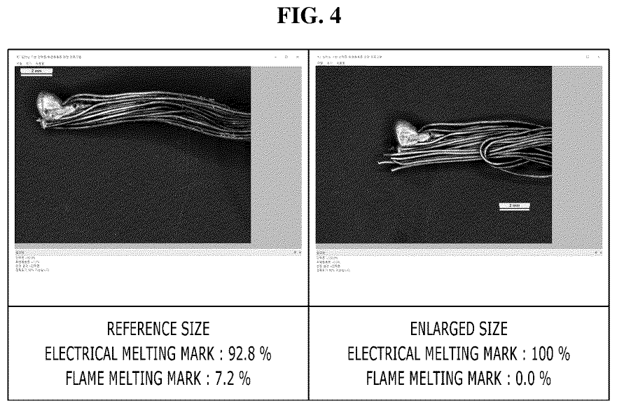

FIG. 4 is a view comparing determination probabilities according to differences in magnification of wire images.

Referring to FIG. 4, at the same rotation angle of the same wire, the photographing body 121 may check a determination probability of a melting trace from images captured at different magnifications. Depending on a difference in magnification of photographing, there is a difference in the probability of determining an electrical melting mark or a flame melting mark. Accordingly, it is preferable to obtain a wire image for each rotation angle in a state in which photographing magnification of the photographing body 121 is kept constant.

The melting trace analysis unit 230, based on a determination probability of a melting trace included in the wire image for each rotation angle, may analyze information related to a determination probability of a melting trace included in a wire.

For example, the melting trace analysis unit 230 may analyze as follows based on comprehensive statistical values related to a determination probability of a melting trace in a wire image for each rotation angle. The melting trace analysis unit 230 may comprehensively analyze a wire image for each rotation angle of one specific wire, and calculate \textcircled{1} positive frequency of an electrical melting mark and a flame melting mark (e.g., the degree to which the determination probability exceeds 90%, where the value of the determination probability can be changed), \textcircled{2} an average determination probability of an electrical melting mark and a flame melting mark, \textcircled{3} maximum and minimum determination probabilities of an electrical melting mark and a flame melting mark, \textcircled{4} a standard deviation of a determination probability of an electrical melting mark and a flame melting mark, and the like.

The melting trace determination unit 240 may determine the melting trace included in the wire according to a set determination condition by analyzing the information.

In more detail, the melting trace determination unit 240 may determine the melting trace included in the wire as a melting trace that satisfies a set determination condition. In addition, the melting trace determination unit 240 may determine ‘indeterminable’ when the melting trace included in the wire does not satisfy the set determination condition.

Even if a determination probability of an electrical melting mark is high at a certain rotation angle, a melting trace may be mis-determined depending on the rotation angle, such as when a determination probability of an electrical melting mark is low at other rotation angles. Thus, the melting trace determination unit 240 may determine by designating a minimum allowable value of each determination probability.

As an embodiment, a melting trace that satisfies a set determination condition may be determined as a melting trace having a higher maximum determination probability value and a standard deviation of a determination probability less than or equal to a reference value from among an electrical melting mark and a flame melting mark.

For example, in the wire 1, when a maximum determination probability of an electrical melting mark is 90% or more, and a maximum determination probability of a flame melting mark is 50% or less, a melting trace of the wire 1 may be determined as an electrical melting mark. To this, a condition that a standard deviation of a determination probability of an electrical melting mark is 10% or less is added, so that the final determination can be made. Thus, if a maximum determination probability of an electrical melting mark is 99.12%, but an average determination probability of an electrical melting mark is 34.51%, it is difficult to determine that it is an electrical melting mark. In this case, it can be determined as ‘indeterminable’.

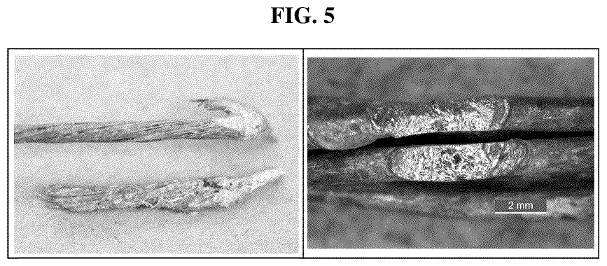

FIG. 5 is a view showing melting traces by a low melting point metal by way of example.

In an actual fire site, many traces of melted low melting point metals such as lead (melting point: 327° C.) and aluminum (melting point: 659° C.) may be found on the wire 1.

For example, as a wire soldered to a substrate is exposed to a flame, lead and a conductor (copper) of the wire 1 are alloyed so that they may be melted even at a temperature lower than the temperature at which copper melts (melting point: 1,085° C.). A melting trace by such a low melting point metal is difficult to determine as an electrical melting mark and may be determined as a flame melting mark.

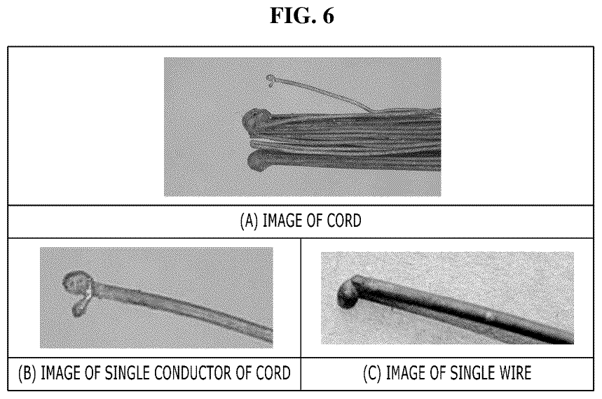

FIG. 6 is a view comparing an image of a single conductor of a cord with an image of a single wire.

The wire 1 may be classified into a single wire, a stranded wire, and cord according to its shape. The single wire is made of one thick conductor, and the stranded wire and cord are made of several conductors. Because cords bend easily, the conductors of the cord are relatively thinner than those of the stranded wire.

Referring to FIG. 6, because an image of only one conductor of the cord is similar to an image of the single wire, mis-determination is likely to occur when a melting trace determination result is classified into a single wire, a stranded wire, and cord using a CNN-based deep learning model. Therefore, it is preferable that the melting trace determination unit 240 according to an embodiment determines only an electrical melting mark and a flame melting mark.

The deep learning-based electric wire-melting trace determination apparatus 20 according to an embodiment may further include a trained model generating unit 250.

The trained model generating unit 250 may generate a pre-trained model using wire images found at a fire, explosion, or arson site as training data. An appraisal report refers to a document that describes an appraisal process and its results based on the expert knowledge and experience of an appraiser. The appraisal report may include images of wires found at fire, explosion, or arson sites, so the wire images included in the appraisal report may be used to generate a pre-trained model.

In addition, the trained model generating unit 250 may be included in the deep learning-based electric wire-melting trace determination apparatus 20, or may be included in a separate external device.

The deep learning-based electric wire-melting trace determination apparatus 20 according to an embodiment may further include a storage unit and a control unit.

The storage unit may store data such as a wire image for each rotation angle. The storage unit may include a volatile memory, a non-volatile memory, or a combination of volatile and non-volatile memories. The storage unit may provide stored data according to a request of the control unit.

The control unit may control all operations of the deep learning-based electric wire-melting trace determination apparatus 20. The control unit may be implemented as one processor or a plurality of processors.

For example, the control unit may control the operation of at least one of the image obtaining unit 210, the trained model application unit 220, the melting trace analysis unit 230, the melting trace determination unit 240, and the trained model generating unit 250.

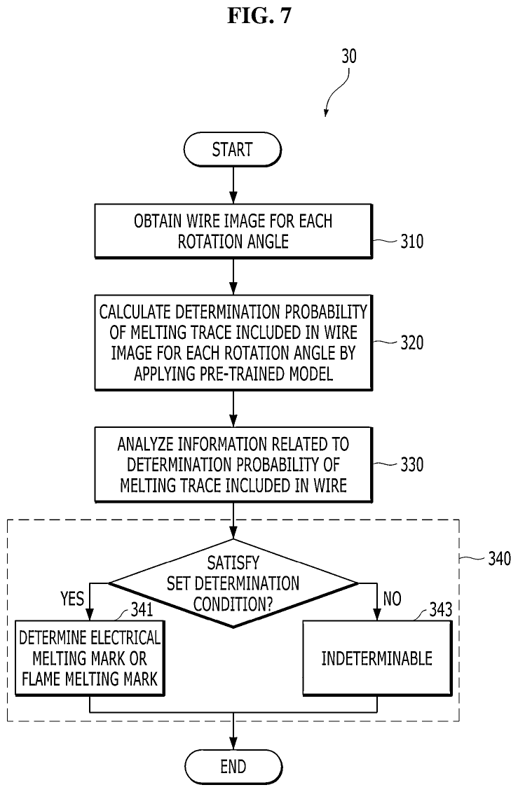

FIG. 7 is a flowchart illustrating a deep learning-based electric wire melting trace determination method according to an embodiment.

Referring to FIG. 7, a deep learning-based electric wire-melting trace determination method 30 according to an embodiment will be described. For convenience of description, the content overlapping with the deep learning-based electric wire-melting trace determination apparatus 20 will be omitted or simplified.

Operation 310 is obtaining a wire image for each rotation angle captured using the wire melting trace photographing apparatus 10 with respect to the wire 1 including a melting trace.

Operation 310 may be performed by the image obtaining unit 210.

For example, the image obtaining unit 210 may obtain a wire image for each rotation angle captured in a circumferential direction of the wire 1 located parallel to a plane in a length direction of the wire 1.

With respect to the wire 1 located parallel to the plane, a wire image may be captured at regular rotation angle intervals while rotating in a circumferential direction about a rotation axis of the wire 1. As described above, it is preferable to photograph a wire image for each rotation angle using the wire melting trace photographing apparatus 10.

The wire image for each rotation angle may be captured at the same magnification. For example, the wire image for each rotation angle may be an image obtained while maintaining the photographing body 121 of the wire melting trace photographing apparatus 10 at the same magnification.

Operation 320 is calculating a probability (determination probability) of determining a melting trace included in the wire image for each rotation angle as an electrical melting mark or a flame melting mark by applying a pre-trained model.

Operation 320 may be performed by the trained model application unit 220.

The pre-trained model applied here may be a CNN-based deep learning model (CNN model).

Operation 330 is analyzing information related to a determination probability of a melting trace included in the wire 1 based on the determination probability of the melting trace included in the wire image for each rotation angle.

Operation 330 may be performed by the melting trace analysis unit 230.

For example, as described above, the melting trace analysis unit 230 may comprehensively analyze a wire image for each rotation angle of one wire, and may calculate positive frequency of an electrical melting mark and a flame melting mark, an average determination probability of an electrical melting mark and a flame melting mark, a maximum determination probability of an electrical melting mark and a flame melting mark, a minimum determination probability of an electrical melting mark and a flame melting mark, or a standard deviation of a determination probability of an electrical melting mark and a flame melting mark.

Operation 340 is determining the melting trace included in the wire 1 according to a set determination condition by analyzing the information.

Operation 340 may be performed by the melting trace determination unit 240.

In more detail, in operation 341, the melting trace determination unit 240 may determine the melting trace included in the wire 1 as a melting trace (electrical melting mark or flame melting mark) that satisfies the set determination condition, and in operation 343, the melting trace determination unit 240 may determine ‘indeterminable’ when the melting trace included in the wire 1 does not satisfy the set determination condition.

The deep learning-based electric wire-melting trace determination method 30 according to an embodiment may further include operation 350 of generating a pre-trained model.

In more detail, operation 350 is generating a pre-trained model using wire images found at a fire, explosion, or arson site as training data.

Operation 350 may be performed by the trained model generating unit 250.

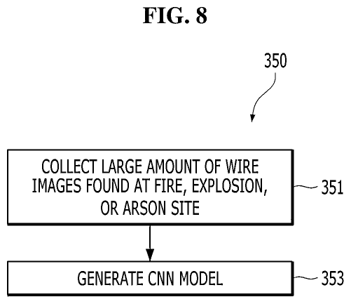

FIG. 8 is a flowchart illustrating generating a pre-trained model according to an embodiment. Referring to FIG. 8, operation 350 may include operations 351 and 353.

Operation 351 is collecting a large amount of wire images found at a fire, explosion, or arson site.

Operation 353 is generating a CNN-based deep learning model (CNN model) by utilizing a large amount of collected wire images.

According to embodiments, by directly rotating a wire or rotating a photographing body in a state where the wire is fixed to photograph the wire, a melting trace may be easily captured at a set rotation angle.

In addition, according to embodiments, a melting trace may be identified more accurately by using CNN, a deep learning technique that classifies images by recognizing unique patterns of images using a large amount of images of electrical melting marks and flame melting marks captured at actual fire, explosion, or arson sites.

In addition, according to embodiments, because melting traces left on a wire are not uniform, and the degree of determination varies depending on the photographing direction, by applying CNN from among deep learning techniques to images captured 360° in a circumferential direction of the wire, the accuracy of determining melting traces may be further improved.

The deep learning-based electric wire-melting trace determination method 30 according to an embodiment shown in FIG. 7 may be written as computer programs and may be implemented in general-use digital computers that execute the programs using a non-transitory computer-readable recording medium. The non-transitory computer-readable recording medium may be a magnetic storage medium (e.g., ROM, a floppy disk, a hard disk, etc.), or an optical reading medium (e.g., a CD-ROM, a digital versatile disk (DVD) or the like).

It should be understood that embodiments described herein should be considered in a descriptive sense only and not for purposes of limitation. Descriptions of features or aspects within each embodiment should typically be considered as available for other similar features or aspects in other embodiments. Therefore, the scope of the disclosure is defined by the appended claims.

What is claimed is:

1. A wire melting trace photographing apparatus comprising:
a wire fixing member connected to one side of a wire including a melting trace, positioning the wire away from a plane, and positioning a rotation axis of the wire parallel to the plane; and
a photographing member capable of photographing the melting trace in a circumferential direction of the wire,
wherein the wire melting trace photographing apparatus photographs the melting trace by directly rotating the wire about the rotation axis of the wire, or photographs the melting trace in a circumferential direction of the wire by operating the photographing member in a state in which the wire is fixed.

2. The wire melting trace photographing apparatus of claim 1, wherein the wire fixing member comprises:
a fixing jig configured to fix one side of the wire to the side of the fixing jig;
a wire fixing portion connected to one side of the fixing jig and located to fix the wire; and
a wire connection portion configured to connect the fixing jig to the wire fixing portion so as to be rotatable about the rotation axis of the wire.

3. The wire melting trace photographing apparatus of claim 1, wherein the photographing member comprises:
a photographing body configured to photograph the melting trace at a close distance;
a photographing body fixing portion connected to one side of the photographing body and located such that the photographing body is fixed; and
a photographing body connection portion configured to rotatably connect the photographing body to the photographing body fixing portion about the rotation axis of the wire.

4. The wire melting trace photographing apparatus of claim 1, further comprising:
a support jig located to support a lower portion of the wire connected to the wire fixing member.

5. A deep learning-based electric wire-melting trace determination apparatus comprising:
an image obtaining unit configured to obtain a wire image for each rotation angle captured using a wire melting trace photographing apparatus with respect to a wire including a melting trace;
a trained model application unit configured to calculate a probability (determination probability) of determining a melting trace included in the wire image for each rotation angle as an electrical melting mark or a flame melting mark by applying a pre-trained model;
a melting trace analysis unit configured to analyze information related to a determination probability of a melting trace included in the wire based on the determination probability of the melting trace included in the wire image for each rotation angle; and
a melting trace determination unit configured to determine the melting trace included in the wire according to a set determination condition by analyzing the information.

6. The deep learning-based electric wire-melting trace determination apparatus of claim 5, wherein the information related to the determination probability of the melting trace included in the wire comprises:
positive frequency of an electrical melting mark and a flame melting mark, an average determination probability of an electrical melting mark and a flame melting mark, a maximum determination probability of an electrical melting mark and a flame melting mark, a minimum determination probability of an electrical melting mark and a flame melting mark, or a standard deviation of a determination probability of an electrical melting mark and a flame melting mark.

7. The deep learning-based electric wire-melting trace determination apparatus of claim 5, further comprising:
a trained model generation unit configured to generate the pre-trained model using wire images found at a fire, explosion, or arson site as training data.

8. The deep learning-based electric wire-melting trace determination apparatus of claim 5, wherein the pre-trained model is a convolutional neural network (CNN)-based deep learning model.

9. A deep learning-based electric wire-melting trace determination method comprising:
obtaining a wire image for each rotation angle captured using a wire melting trace photographing apparatus with respect to a wire including a melting trace;
calculating a probability (determination probability) of determining a melting trace included in the wire image for each rotation angle as an electrical melting mark or a flame melting mark by applying a pre-trained model;
analyzing information related to a determination probability of a melting trace included in the wire based on the determination probability of the melting trace included in the wire image for each rotation angle; and
determining the melting trace included in the wire according to a set determination condition by analyzing the information.

10. The deep learning-based electric wire-melting trace determination method of claim 9, further comprising:
generating the pre-trained model using wire images found at a fire, explosion, or arson site as training data.

11. The deep learning-based electric wire-melting trace determination method of claim 9, wherein the wire image for each rotation angle is an image captured at the same magnification.
